(19) United States
(12) Patent Application Publication
(10) Pub. No.: US 2003/0068907 A1
(43) Pub. Date: Apr. 10, 2003

(54) Hermetically sealed package

(76) Inventors: Caesar Morte, Lakewood, NJ (US); Robert J. Satriano, Hackettstown, NJ (US)

Correspondence Address: Henry I. Schanzer, Esq., 29 Brookfall Rd., Edison, NJ, 08817, US

(21) Appl. No.: 10/158,509

(22) Filed: May 30, 2002

Related U.S. Application Data
(60) Provisional application No. 60/327,978, filed on Oct. 9, 2001.

(51) Int. Cl. H05K 1/00; H01R 12/00

(52) U.S. Cl. 439/70

(57) ABSTRACT

A package embodying the invention includes a base plate for receiving an electronic device having input/output points to be connected to an external system. Side walls mounted on the base plate enclose the electronic device. Selected side walls have a plurality of hermetically sealed openings through which are passed conductive leads which extend from within the package to outside the package for connecting the electronic device to the external system. A ceramic insert is mounted on the inside of at least one of the side walls. The ceramic insert has a first set of holes (terminals) for the direct contacting and connection thereto of selected conductive leads. The ceramic insert also has a second set of terminals whose layout is customized for optimally connecting selected ones of the second set of terminals to selected input/output points of the electronic device. The ceramic insert also includes a custom designed conductive pattern interconnecting selected ones of the first and second set of terminals.

### CROSS REFERENCE TO RELATED APPLICATIONS

This application claims priority from provisional patent application Serial Number 60/327,978 filed Oct. 09, 2001 for Hermetically Sealed Package in the name of Robert J. Satriano and Caesar Morte.

### BACKGROUND OF THE INVENTION

This invention relates to an improved hermetically sealed package.

To better understand the description of the invention to follow, reference is made to FIG. 1 which shows a presently available hermetically sealed dual-in-line (DIL) package. The package of FIG. 1 includes a base, B1, with side walls (W1, W2, W3, and W4) mounted on the base. The base B1 may be formed of copper or tungsten copper, or any other suitable material, to provide good heat conduction. Mounted in, and secured to, each one of two opposing side walls is a multi-layered ceramic insert (C1, C2) which extends from the outside of each sidewall to the inside of each sidewall. In FIG. 1, a portion C2A of insert C2 is shown extending outside of wall W2 and a portion C1B of insert C1 is shown extending inside wall W1. The side walls may be formed of Kovar or any other suitable material which has a thermal coefficient of linear expansion which matches that of the of the ceramic insert. By way of example, the package of FIG. 1 is shown to have 14 leads (L1-L14), with seven spaced apart leads (L1-L7 and L8-L14) on each side. These leads extend from the outside of the package to various regularly spaced apart points on the ceramic insert. Each ceramic insert is formed of multi layers to enable “vias” to allow electrical continuity from a selected one of the leads to certain points/terminals on the inside portion of the ceramic insert.

There are several disadvantages to the package and structure shown in FIG. 1. The multi-layered ceramic structure is very complicated in design and therefore expensive and difficult to manufacture. The multi-layered rectangular ceramic inserts mounted in and secured to, and within, the side walls make it difficult to provide and sustain a good hermetic seal along the edges and corners of the ceramic insert, between the ceramic insert and the walls of the package. To ensure a good seal the entire outer periphery of the ceramic insert must be “brazed” to the corresponding walls of the package. However, brazing the rectangular multi-layered ceramic inserts into the sidewalls is subject to manufacturing yield loss.

Also, for the example of FIG. 1, fourteen external leads, seven on each side need to be individually attached to the multi-layer ceramic insert during, or after, the package is hermetically sealed.

The package of FIG. 1 with its ceramic insert and leads in place can be used to manufacture only one dedicated product. For example, a selected electronic circuit, for which a package and its ceramic insert was designed, can be mounted inside the package and connections can then be made between terminals on the electronic circuit and selected points on the multi-layer ceramic insert. However, the basic package with its ceramic insert and leads in place can not be used interchangeably with any other electronic circuit. That is, the leads and the ceramic insert of the prior art form a dedicated application circuit which can be used for, and in, the manufacture of only one type of dedicated product. Thus each different product needs its own particular and specifically designed lead and ceramic insert assembly.

The defects and disadvantages discussed above are not present in packages formed in accordance with the invention.

### SUMMARY OF THE INVENTION

A hermetically sealed package embodying the invention includes a base plate for receiving an electronic (or electro-optic) device having input/output points to be connected to an external system. A plurality of side walls mounted on the base plate function to physically surround the electronic device. Selected side walls have a plurality of hermetically sealed openings through which conductive leads are passed and which extend from within the package to outside the package for connecting the electronic device to the external system. A ceramic insert is mounted adjacent to (or along) the inside of at least one of the side walls. The ceramic insert has a first set of terminals (e.g., holes) for connecting to selected conductive leads. The ceramic insert also has a second set of terminals which are laid out and arranged to optimally connect selected ones of the second set of terminals to selected input/output points of the electronic device. The ceramic insert also includes a custom designed conductive pattern interconnecting selected ones of the first and second set of terminals.

The locations of the second set of terminals on the ceramic insert are normally dictated by requirements associated with the electronic device. These requirements include electrical and signal considerations which optimize the operation of the electronic (or electro-optical) device, (e.g., the shortest connection from an input or output point on the electronic device to a terminal on the ceramic insert.). The location of the first set of terminals is normally dictated by the external system and packaging considerations. The ceramic insert thus functions as a “wiring” interface enabling a standardized external conductive lead configuration to be compatible with an internally customized interconnecting distribution system for optimizing the operation and interconnection of an electronic device placed in an hermetic package.

In one embodiment, the ceramic insert functions as a “wiring” interface between regularly spaced conductive leads in the sidewalls of the package terminating at a first set of terminals and the second set of terminals laid out to optimize their connection to the input and output points (I/O) of an electronic device mounted on the base plate of the package.

In one embodiment of the invention, the portion of the conductive leads extending within the package also functions as a means to support the ceramic insert and secure it in position.

In one embodiment, the package is made by forming openings (i.e., holes) in selected sidewalls and filling selected openings with a glass preform and passing a conductive lead through each glass preform which physically and electrically isolates the conductive leads from the sidewalls. Part of each conductive lead extends within the package and part extends outside the package. Then, a hermetic seal is formed between each lead and its glass preform and between the glass preform and the sidewalls. Subsequently, selected ones of the first terminals of the ceramic insert may be directly connected to selected ones of the conductive leads to form an electrical connection and the conductive leads may be used to physically secure the ceramic insert alongside the inner portion of the sidewall.

In another embodiment, the package may be formed by first passing conductive leads through a first set of terminals of the ceramic insert and then passing the leads through glass preforms filling openings in the sidewalls. Subsequently, a hermetic seal is formed between the leads and glass preform and between the glass preform and the sidewall openings.

### BRIEF DESCRIPTION OF THE DRAWINGS

In the accompanying figures like reference characters denote like components, and

FIG. 1 is an isometric diagram of a prior art package;

FIG. 2 is an isometric diagram of a package formed in accordance with the invention;

FIGS. 2A1 and 2A2 are isometric diagrams of two different views of a ceramic insert to be mounted on conductive “leads” in accordance with the invention;

FIG. 2B is an idealized, functional diagram of the ceramic insert in packages embodying the invention;

FIG. 3 is a front view of a package wall embodying the invention;

FIG. 4 is a top cut-away view of a ceramic insert mounted on a sidewall;

FIG. 5A is a top view of a package (with the lid removed) embodying the invention in which a laser chip is mounted;

FIG. 5B is a cross sectional diagram of a portion of FIG. 5;

FIG. 5C is an isometric diagram of a package with an electronic device mounted on the base of the package; and

FIG. 6 is an isometric diagram of a package with a lid sealing the package.

### DETAILED DESCRIPTION OF THE INVENTION

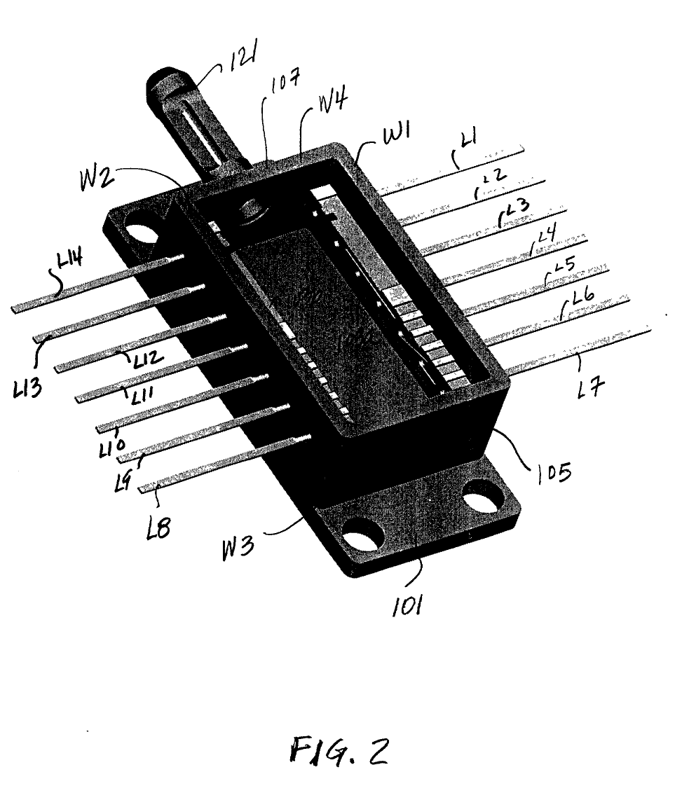

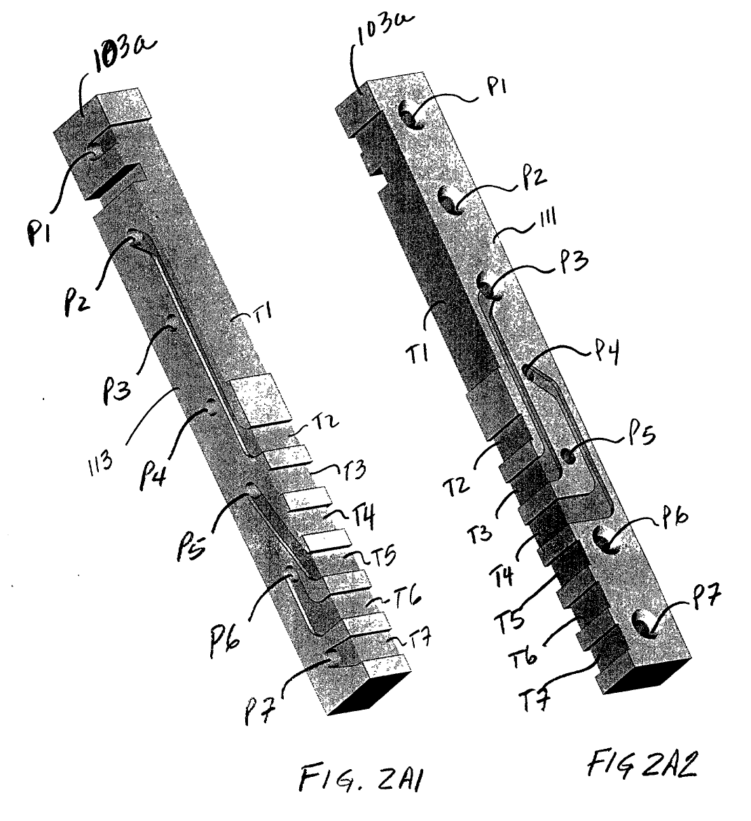

Applicants' invention may be explained beginning with reference to the package shown in FIG. 2. The package of FIG. 2 includes a base 101 which may be formed of copper or tungsten copper or any suitable material for providing good thermal conduction (heat sinking capability). The body of the package includes four side walls (W1, W2, W3, W4) which are mounted on the base 101. The walls may be formed of Kovar (iron nickel cobalt) or any other suitable material. Kovar is selected because its expansion coefficient matches that of glass. However, any other suitable material may be used.

In the package shown in FIG. 2, conductive leads (e.g., L1-L14) are mounted on two opposite side walls (e.g., W1, W2). The leads are mounted and secured to the side walls by means of glass performs (e.g., glass beads located in holes in the walls). The leads extend from outside each side wall to a short distance beyond the inside of each side wall. By way of example, in the package of FIG. 2 and as shown in FIGS. 2A1, 2A2, 3 and 4, seven spaced apart openings (i.e., holes) are formed along a wall (e.g., W1). The openings may be formed by “punching” holes in the side walls (except for the one opening formed to hold a ground lead). Each opening is filled with a glass preform (e.g., a glass bead) which may have a generally toroidal (“doughnut”) shape with a hole in the middle (e.g., like a life saver). In one embodiment, the leads are inserted in the holes in the glass preform (which may also be referred to as a glass bead). A glass preform with its associated conductive lead passing through its hole is then inserted in each one of the openings of the sidewalls. The leads which may be of Kovar, or any other suitable electrically conductive material, are inserted through their respective glass preform (bead) and extend a desired distance beyond the inside surface of a wall. The glass preform and the conductive leads are held in place in the sidewalls of the package by means of one or more fixtures (not shown). The fixture(s) holding the package assembly is then placed in a furnace to heat the package to the melting point of the glass preforms. The furnace is then cooled, or the package is withdrawn from the furnace and cooled. As a result, the glass solidifies and the desired hermetic seal is produced between the sidewalls and the glass performs and between the glass preforms and the leads of the package. Thus, the fixture (not shown) holds the conductive leads in place until the glass cools down and solidifies. Upon cooling, the leads are attached to the walls in manner which provides an air tight and secure hermetic seal. The package formed with the conductive leads attached may be used in many different applications and to house many different circuits, as discussed below.

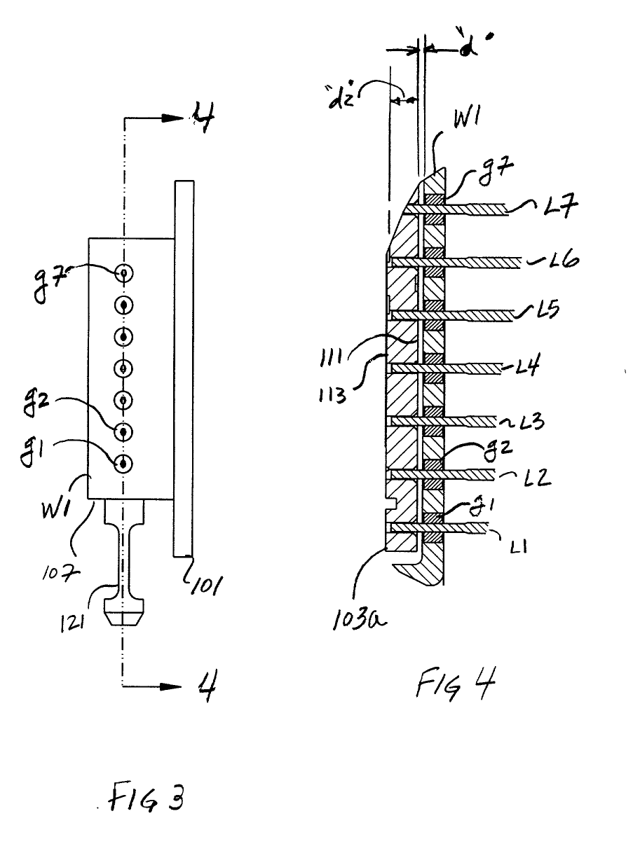

In FIG. 2, a unitary ceramic insert (103a, 103b) is shown to be mounted adjacent to, and/or alongside, the inside portion of each side wall (see also FIG. 4). The ceramic insert is manufactured with a predetermined interconnect pattern, as illustrated in FIGS. 2A1, 2A2 and 2B. Each ceramic insert has one (“inside”) surface (e.g., 111) designed to face the inside wall and another (“outside”) surface (e.g., 113) designed to face away from the inside wall. The ends of selected ones of the holes/terminals terminating on surface 111 are countersunk to enable the ceramic insert to be more easily mounted on the leads extending within the package. The ceramic insert contains “vias” (e.g., X1-X7, and X8-X14) to provide conductivity between selected ones of the leads (e.g., L1-L14) and various pads/terminals (e.g., T1-T7, T8-T14) along the ceramic insert. Each ceramic insert (e.g., 103a, 103b) is shown mounted adjacent to and along the inside of the side wall. In the embodiment of FIG. 2, the ceramic insert is mounted on the portion of the leads extending within the package enclosure (i.e., ceramic insert 103a is mounted on leads L1-L7, as shown in FIG. 4, and ceramic insert 103b is mounted on leads L8-L14). The conductive leads (e.g., L1-L7) extend inside the package and make contact with the internal walls of the holes/pins (e.g., P1-P7) within the ceramic insert which have been appropriately metallized. Note that the conductive leads extend a sufficient distance (e.g., d2, which is approximately equal to the width of the ceramic insert) to fit through the metallized holes (terminals/pins) formed in the ceramic insert facing the inside walls of the package; see FIGS. 2A1, 2A2 and 4. The ends of the leads extending through (or nearly through) the ceramic insert may be brazed or soldered to their respective pin/hole terminals within or at the surface 113 of the ceramic insert distal from the inside wall. This ensures good contact between the conductive leads and their respective metallized holes/pins in the ceramic and that the leads support their associated ceramic insert and secure it along the side wall. The feature of enabling the conductive leads to be either brazed or soldered to the ceramic insert provides a significant advantage. Thus, the ceramic insert may be mounted within the package and brazed to the leads at the same time as the leads are inserted and sealed to the walls of the package. Alternatively, the ceramic insert may be mounted on the leads and soldered to the leads after the leads have been affixed to the walls of the package, e.g., contemporaneously with the attaching of a selected electronic device on the base of the package.

FIG. 2B is an idealized drawing illustrating the function performed by the ceramic insert. For purpose of illustration two opposite side walls (W1, W2) are shown. By way of example, conductive leads (e.g., L1-L7 and L8-L14) may be passed through sidewalls (e.g., W1 and W2) and hermetically glass sealed in position (see FIGS. 2, 2A, 2C1 and 2C2). A ceramic insert (e.g., 103a) may be mounted adjacent to the inside of a wall (e.g., W1) by means of passing (or threading) the conductive leads into the corresponding holes in the ceramic insert. Alternatively, the ceramic insert may also be secured by means of securing tabs 121a, 121b. In either event, the preformed terminals/pins/holes in each ceramic insert is connected to conductive leads (e.g., P1-P7 to L1-L7). The spaced apart conductive leads (e.g., L1-L7) terminate at, or within, corresponding contact points (e.g., P1-P7) located in the ceramic insert (e.g., 103a). The pins/posts/holes (e.g., P1-P7) on (and in) the ceramic insert are interconnected to pads (terminals), such as T1-T7, by means of “vias” preformed and patterned on (and/or within) the ceramic insert. The terminals (e.g., T1-T7) are located on the ceramic insert at those locations which are deemed to be the best locations for connection to the input /output (I/O) points of a device 200. Device 200 may be any electronic or electro-optical device which it is desired to place in an hermetically sealed package. An “electronic device”, as used herein and in the appended claims, includes any electro-optic device and/or any “device”, circuit, or chip to which, and from which, connections are made to an external system.

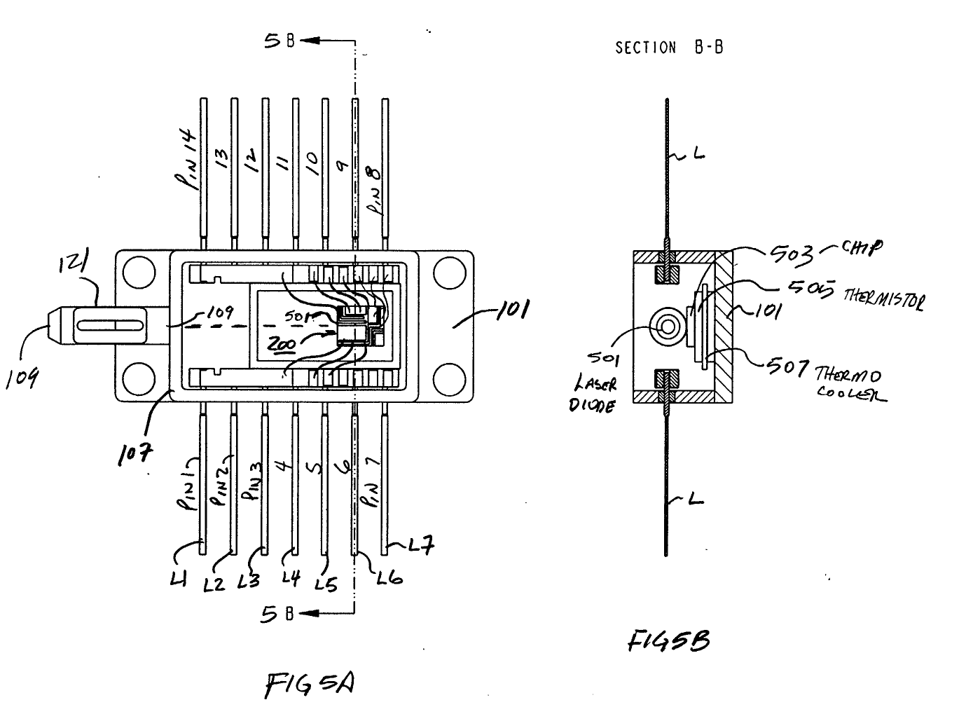

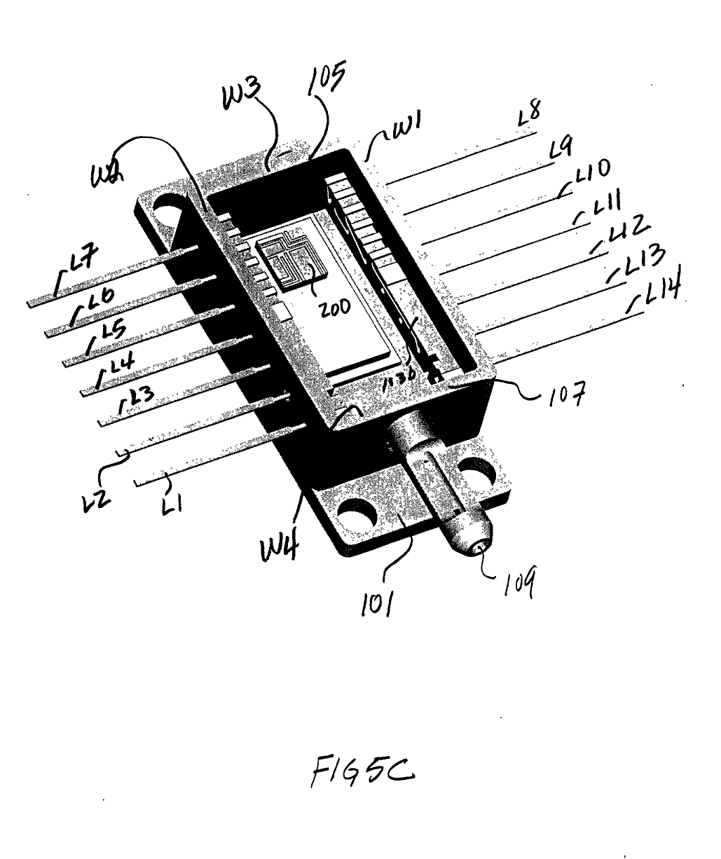

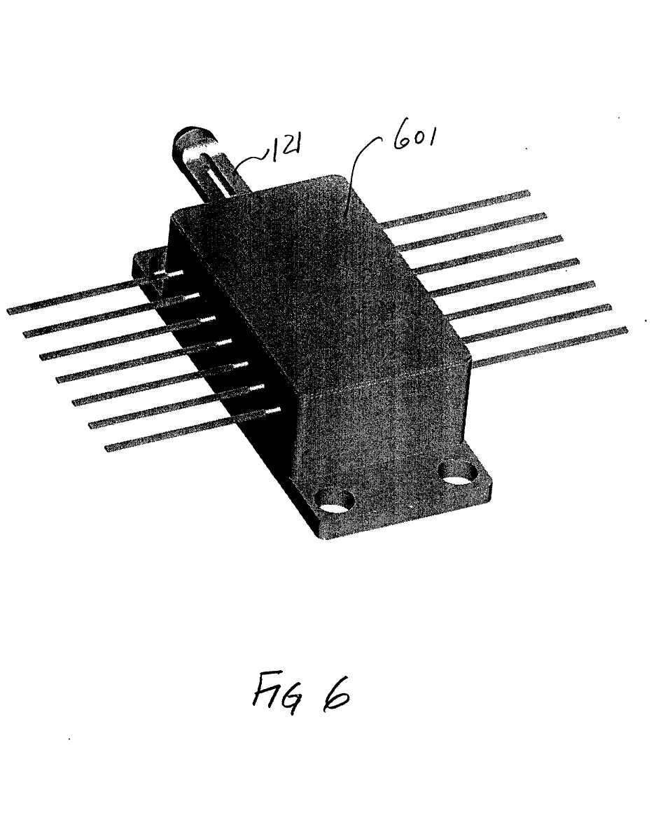

As shown in FIGS. 2B, 5A and 5C, the device 200 may be asymmetrically located at one extremity of the package (e.g. the rear, the front or one of the sides) and its I/O points may also be offset relative to the regularly spaced conductive leads. Thus, as illustrated in FIG. 2B, the I/O points of the circuit may be appropriately connected to one end of the ceramic insert. The ceramic insert is then used to redistribute the I/O points connected to a cluster of irregularly terminated pads to the spaced apart conductive leads. Thus, by way of example, in FIG. 2B terminal P1 is connected to T2 by means of “via” X1; P2 is connected to T3 by means of “via” X2; P3 is connected to T4 by means of “via” X3; P4 is connected to T1 by means of “via” X4, etc..

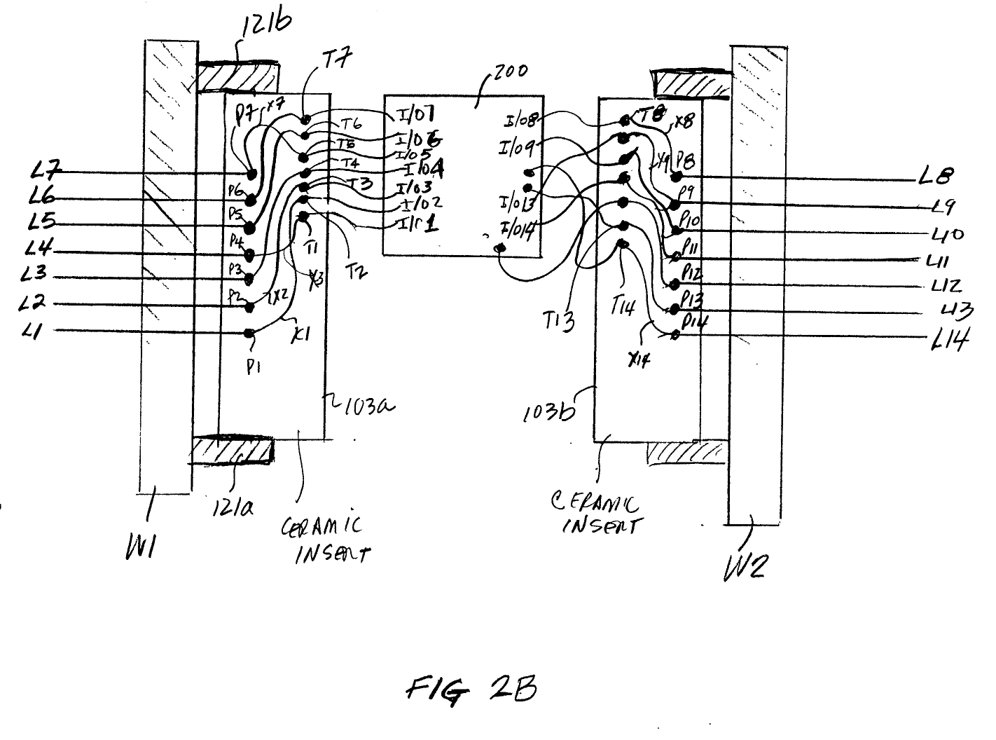

FIG. 4 shows that corresponding to each conductive lead (e.g., L1-L7) there is a “through hole” in the ceramic insert which extends from the “inside” surface 111 to the “outside” surface 113 of the insert. As shown in FIGS. 3 and 4, each lead (e.g., L1-L7) passes through its respective glass bead (e.g., g1, g2, g7) which provides electric isolation and insulation between the leads and the wall while providing an hermetic seal. Also, the surface 111 is offset from the side wall by a distance, d, to ensure that the pins (e.g., P1-P7) do not touch the side wall. An interconnecting pattern (including “vias”) formed on, and within, the ceramic insert connects selected holes (e.g., P1-P7) to selected pads/terminals (e.g., T1-T7) located on a surface of the ceramic insert. As shown in FIGS. 2B and 5A, the input/output points of a device 200 attached to the base of the package are eventually connected to the pads/terminals (e.g., T1T-7). The ceramic insert functions as a “wiring” interface between the “device” 200 to be mounted (or affixed) on the base of the package and the regularly spaced input/output leads in the sidewalls of the package. The pads (terminals) on the ceramic insert are located (and customized) to provide appropriate connections to the device 200 (which may be any desirable chip/circuit) to meet electrical and/or power considerations. The interconnecting pattern of vias formed on the ceramic insert then couples the pads (whose locations are customized for the device mounted on the base of the package) to points on the insert which pick up the regularly space leads whose layout and arrangement are dictated by the external system and packaging considerations.

By way of example, FIGS. 5A, 5B and 5C show an electronic device (e.g., an assembly 200 which in this embodiment includes a laser chip) mounted on the base 101 with a laser beam projecting towards the front wall 107 and through the opening 109 of an extension/directing/aiming member 121. The assembly 200 is mounted near the back end of the package, on the base 101 of the package. The electronic package may include a laser diode 501, an integrated circuit (IC), 503, for controlling the laser diode, a thermistor 505 for sensing the temperature of the IC 503, and a thermocooler for controlling the temperature of the assembly. All these components are located in the back of the package. Thus, the power and signal leads for the assembly are located in a cluster in the back of the package. For proper operation of the assembly and its components, certain of the signal and power leads must be kept as short as possible or arranged in a preferred manner. Therefore, the connections between the I/O points on the chip (see also FIG. 2B) and the pads on the ceramic insert (shown as terminals T1-T7 and T11-T14) in FIG. 2B must be customized for optimizing the operation and function of the assembly 200. Perforce, the set of terminals (e.g., T1-T7 and T11-T14) for directly interconnecting to the chip 200 may be in a cluster at one end of the package, or otherwise irregularly laid out, to accommodate and optimize the operation of the assembly 200. As may be seen from FIG. 2B, the ceramic insert is configured with vias (wired) to redistribute the signals and power from the “customized” pads (e.g., T1-T7) to the regularly spaced terminal points (P1-P7) to which the leads (L1-L7) are connected.

Note that for the embodiment of FIGS. 5A, 5B and 5C the device was a laser based circuit. However, it should be understood that the assembly 200 may be replaced by any one of many different circuits.

It should be appreciated that the package may be formed in at least one of the following two ways:

(a) the leads may be inserted into glass performs embedded in openings in the side walls and be hermetically sealed in and to the side walls. In this instance the leads may be hermetically sealed to the package before the ceramic insert(s) is/are mounted within the package. Then, holes pre-formed in the ceramic insert and whose interior surfaces have been plated with a conductive material (which function as termination for the leads and which for ease of description may be also referred to as pins or points) are used to mount the ceramic insert on the leads. Then, as discussed above, the leads may be selectively brazed and/or soldered to the conductive material (e.g., metal) on the inside surface of the holes providing good electrical contact. Then, an electronic device is mounted within (e.g., on the base of) the package and connections are made between the I/O points of the electronic device and the pads (terminals) pre-formed on the ceramic insert. These connections may be made by wire bonding the I/O points to the pads.

(b) Alternatively, “nail head” leads may be inserted into the ceramic insert and secured (brazed or soldered) to the ceramic insert. The leads are passed from inside the package, through the ceramic insert and then through pre-formed holes in the side walls, extending on the outside of the sidewalls. The “nail head” functions as a button holding the ceramic insert against the sidewalls. In this instance the package would be hermetically sealed after the mounting of the ceramic insert(s) inside the package.

With the ceramic insert mounted adjacent to the sidewalls the device of interest is then mounted on the base of the package, within the sidewalls, and connections are then made (e.g., by wire bonding) from the device of interest to the various pads (terminals) on the ceramic insert.

Certain of the advantages of packages embodying the invention and shown in FIGS. 2, 2A1, 2A2, 2B, 3, 4 and 5a, 5B and 5C are as follows:

1. A single one piece ceramic insert with pre-determined conductive paths and vias may be mounted in a selected location. The ceramic insert can be placed along any of the walls of the package and may extend for the full length of the wall.

2. The conductive leads are glass sealed on the side walls of the package creating a hermetic internal chamber isolated from the outside world. The leads are sealed in glass and extend internally and externally to the package. Note that selected leads (e.g., the lead for distributing “power ground”) need not be passed through a glass preform; they may be brazed to the side walls and still provide hermeticity.

3. The package can be easily manufactured in stages. The basic package including the base and the side walls can be manufactured and put together without the need to attach a ceramic insert. The leads can be attached to the walls prior to the mounting of the ceramic insert. The ceramic insert with specific and customized or unique patterns can be formed and added later to accommodate various different products. That is, the entire shell of the package can be manufactured without the ceramic interconnecting insert which can be subsequently added when the product is defined (i.e., when components are to be mounted within the package).

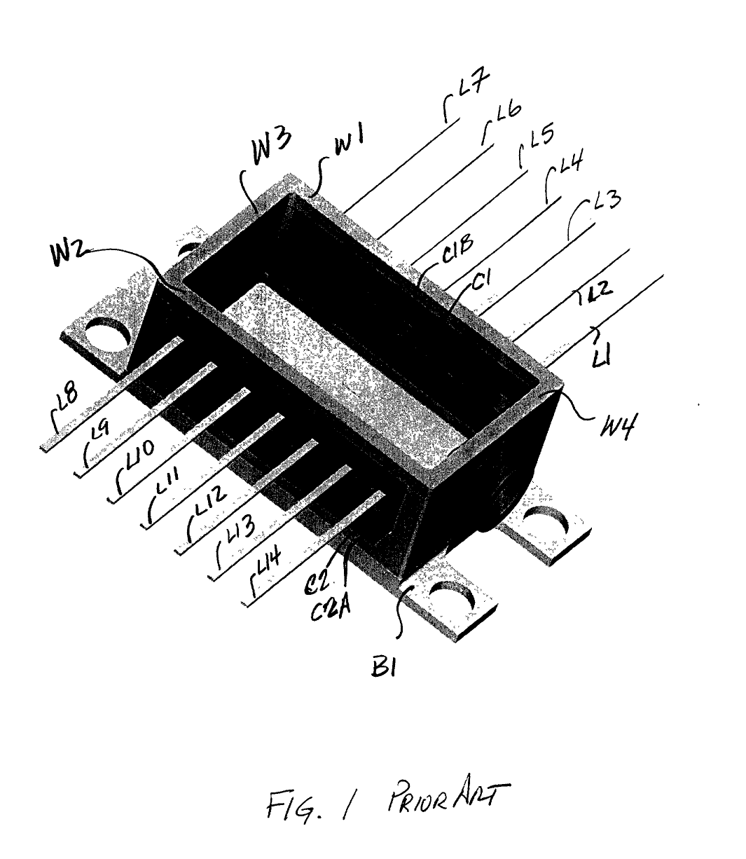

4. The glass to metal seal of the leads to the side walls is more economical and tends to produce higher yields than the rectangular multi-layered ceramic insert of the prior art shown in FIG. 1.

5. Packages embodying the invention provide the flexibility to have different plating schemes on the package. It also allows for nickel plating lids to be used. See FIG. 6 which shows an isometric of a package with a lid covering the top of the package.

What is claimed is:

1. A hermetically sealed package comprising:
a base plate for mounting thereon an electronic device having a multiplicity of input and output terminals;
a plurality of side walls mounted on the base plate defining an enclosure about the electronic device; at least one of the side walls having a plurality of hermetically sealed openings through which a plurality of conductive leads extend from within the package to outside the package; the conductive leads for providing electrical connections between the electronic device and an external system; and
a ceramic insert mounted on the inside of at least one of the side walls, said ceramic insert having a first set of terminals for the direct connection thereto of selected ones of said plurality of conductive leads, said ceramic insert having a second set of terminals for the direct connection of the second set of terminals to selected ones of the multiplicity of input and output terminals of the electronic device; and said ceramic insert having a predetermined pattern for interconnecting selected ones of the first and second set of terminals.

2. The hermetically sealed package as claimed in claim 1 wherein the conductive leads are generally uniformly spaced along the length of the wall, wherein the first set of terminals are through-holes formed in the ceramic for contacting and mating with corresponding leads, and wherein the layout of the second set of terminals is designed to optimize their connection to the multiplicity of input and output terminals of the electronic device.

3. The hermetically sealed package as claimed in claim 2, wherein the ceramic insert is mounted adjacent to the inside wall and supported along the side wall by connecting the first set of terminals to the conductive leads.

4. The hermetically sealed package as claimed in claim 2, wherein each one of the hermetically sealed openings includes a glass bead located within the opening, with a conductive lead passing through the glass bead, and the glass bead isolating and insulating the conductive lead from the side wall, while providing an hermetic seal.

5. The hermetically sealed package as claimed in claim 2, wherein the enclosure is of generally rectangular shape, and wherein at least two of the walls include a plurality of hermetically sealed openings through which a plurality of conductive leads extend from within the package to outside the package.

6. The hermetically sealed package as claimed in claim 2, wherein the electronic device includes an optical signal amplifier.

7. The hermetically sealed package as claimed in claim 1, wherein the first set of terminals are plated with a conductive material, and wherein the conductive leads are brazed to respective terminals.

8. The hermetically sealed package as claimed in claim 1, wherein the first set of terminals are plated with a conductive material, and wherein the conductive leads are soldered to respective terminals.

9. The hermetically sealed package as claimed in claim 1, wherein an electronic device having a plurality of input and output terminals is mounted on the base of said package; and wherein selected ones of said input and output terminals are connected to said second set of terminals.

10. A method for forming a hermetically sealed package, where the package includes a base on which is to be mounted an electronic device having a multiplicity of input and output points to be connected to an external system and wherein the package includes sidewalls mounted on the base and forming an enclosure surrounding the electronic device, with leads extending from within the package enclosure to outside the package for connecting the electronic device to the external system, comprising the steps of:
mounting a ceramic insert on the inside of at least one of the side walls, said ceramic insert having a first set of terminals for the direct connection thereto of selected ones of said leads, said ceramic insert having a second set of terminals for directly connecting the second set of terminals to the electronic device; and said ceramic insert having a customized conductive pattern for interconnecting selected ones of the first and second set of terminals;
connecting selected ones of the leads to selected ones of the first set of terminals; and
connecting selected ones of the input and output points of the electronic device to selected ones of the second set of terminals.

11. The method as claimed in claim 10, wherein the leads are first passed through the sidewalls and a hermetic seal is formed between the leads and the sidewalls and the ceramic insert is then mounted on the leads and secured.

12. The method as claimed in claim 10, wherein the placement of the second set of terminals is arranged to optimize their connections to the electronic device.

13. A method for forming a hermetically sealed package, where the package includes a base on which is to be mounted an electronic device having a multiplicity of input and output points to be connected to an external system and wherein the package includes sidewalls mounted on the base and surrounding the electronic device, with leads extending from within the package to outside the package for connecting the electronic device to the external system comprising the steps of:
mounting conductive leads in hermetically sealed openings in the sidewalls, with the conductive leads extending externally to and internally to the enclosure;
mounting a ceramic insert on the inside of at least one of the side walls, said ceramic insert having a first set of terminals for the direct connection thereto of selected ones of said leads, said ceramic insert having a second set of terminals for the direct connection of the second set of terminals to the electronic device; and said ceramic insert having a unique conductive pattern interconnecting the first and second set of terminals;
connecting selected ones of the leads to selected ones of the first set of terminals; and
connecting selected ones of the input and output points of the electronic device to selected ones of the second set of terminals.

14. The method as claimed in claim 13, wherein the first set of terminals are holes preformed in the ceramic insert, the inner surface of the holes being rendered conductive for contacting their corresponding leads.

15. A hermetically sealed package comprising:
a base plate for holding an electronic device having a multiplicity of input and output points;
a plurality of side walls mounted on the base plate having a plurality of glass sealed openings through which leads extend from within the package to outside the package, the leads for connecting the electronic device to an external system; and
an insert for coupling selected leads to selected input and output points of the electronic device, said insert being mounted on the inside of at least one of the side walls, said insert having a first set of terminals for the direct connection thereto of selected leads, said insert also having a second set of terminals arranged for optimizing the connection of selected ones of the second set of terminals to selected input and output points of the electronic device; and
said insert having a customized conductive pattern for interconnecting selected ones of the first and second set of terminals.

16. The hermetically sealed package as claimed in claim 15 wherein the insert is a ceramic insert, and wherein the leads are generally uniformly spaced along the length of the wall.

17. The hermetically sealed package as claimed in claim 16, wherein the leads extending within the package are connected to the insert so as support the ceramic insert and hold it against the wall.
